(19) United States
(12) Patent Application Publication
(10) Pub. No.: US 2026/0148726 A1
(43) Pub. Date: May 28, 2026

(54) SOUND ABSORPTION STRUCTURE AND SERVER

(71) Applicants: INVENTEC (PUDONG) TECHNOLOGY CORPORATION, Shanghai (CN); INVENTEC CORPORATION, Taipei City (TW)

(72) Inventors: Hsin-Haou HUANG, Taipei City (TW); Teng-Shan HU, Taipei City (TW); Po-Hsiu CHEN, Taipei City (TW); Hsieh-Liang TSAI, Taipei City (TW)

(73) Assignees: INVENTEC (PUDONG) TECHNOLOGY CORPORATION, Shanghai (CN); INVENTEC CORPORATION, Taipei City (TW)

(21) Appl. No.: 19/226,637

(22) Filed: Jun. 3, 2025

(30) Foreign Application Priority Data
Nov. 25, 2024 (CN) 202411703150.9

(51) Int. Cl. G10K 11/172; H05K 7/20

(52) U.S. Cl. CPC G10K 11/172; H05K 7/20736

(57) ABSTRACT

A sound absorption structure includes at least one sound absorption unit. The sound absorption unit includes a plurality of sub units, the sub units are arranged in an array and connected to one another to surround a sound permeable slot together. Each of the sub units comprises a plurality of sound absorption chambers and a plurality of connecting channels, the sound absorption chambers and the connecting channels communicate with one another. One of the connecting channels of at least one of the sub units communicates with the sound permeable slot.

### CROSS-REFERENCE TO RELATED APPLICATIONS

This non-provisional application claims priority under 35 U.S.C. § 119(a) on Patent Application No(s). 202411703150.9 filed in China, on Nov. 25, 2024, the entire contents of which are hereby incorporated by reference.

### BACKGROUND OF THE INVENTION

### Technical Field of the Invention

The invention relates to a sound absorption structure and a server.

### Description of the Related Art

In response to the increasing computational demands, the performance of server continues to improve, which also results in significant heat generation. Fans, commonly used in thermal management systems, provide enhanced cooling performance but also lead to increased fan noise. Noise at specific frequencies may adversely affect the performance of storage device.

Currently, the most common noise reduction approach involves attaching low-cost passive noise reduction components to the inner side of the chassis and the backplane of the storage device to minimize the impact of noise on storage performance. However, the noise reduction effect of these components often falls short of expectations and fails to effectively mitigate noise in specific frequency bands, particularly those that are sensitive and likely to interfere with the read/write performance of the storage device. Therefore, researchers in this field are actively working to address the aforementioned issues.

### SUMMARY OF THE INVENTION

The invention provides a sound absorption structure and a server that can effectively prevent noise generated by the fan from affecting the performance of the storage device.

One embodiment of the invention provides a sound absorption structure. The sound absorption structure includes at least one sound absorption unit. The sound absorption unit includes a plurality of sub units, the sub units are arranged in an array and connected to one another to surround a sound permeable slot together. Each of the sub units comprises a plurality of sound absorption chambers and a plurality of connecting channels, the sound absorption chambers and the connecting channels communicate with one another. One of the connecting channels of at least one of the sub units communicates with the sound permeable slot.

Another embodiment of the invention provides a server. The server includes a casing, a hard disk module, a fan module and a sound absorption structure. The casing includes a hard disk storage area and a fan storage area. The hard disk module is disposed in the hard disk storage area. The fan module is disposed in the fan storage area. The sound absorption structure is disposed between the hard disk storage area and the fan storage area. The sound absorption structure includes at least one sound absorption unit. The sound absorption unit includes a plurality of sub units, the sub units are arranged in an array and connected to one another to surround a sound permeable slot together. Each of the sub units comprises a plurality of sound absorption chambers and a plurality of connecting channels, the sound absorption chambers and the connecting channels communicate with one another. One of the connecting channels of at least one of the sub units communicates with the sound permeable slot.

According to the sound absorption structure and the server as discussed in the above embodiments, the sound absorption structure is disposed between the hard disk storage area and the fan storage area, the sub units of the sound absorption unit of the sound absorption structure are arranged in the array and connected to one another to surround the sound permeable slot together, the sound absorption chambers and the connecting channels of each of the sub units communicate with one another, and one of the connecting channels of at least one of the sub units communicates with the sound permeable slot. By the aforementioned configuration, the sound generated by the fan module can enter the sound absorption chambers through the connecting channels of the sub unit and be dissipated, thereby effectively reducing the noise transmitted from the fan module to the hard disk module and preventing the noise from affecting the performance of the hard disk module.

### BRIEF DESCRIPTION OF THE DRAWINGS

The present invention will become more fully understood from the detailed description given hereinbelow and the accompanying drawings which are given by way of illustration only and thus are not limitative of the present invention and wherein:

FIG. 1 is a schematic view of a server according to one embodiment of the invention;

FIG. 2 is a partial schematic view of a sound absorption structure in FIG. 1;

FIG. 3 is a schematic view of a sound absorption unit of the sound absorption structure in FIG. 2; and

FIG. 4 is a schematic view of the deformed sound absorption unit in FIG. 3.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present invention, such as technical and scientific terms, have its own meanings and can be comprehended by those skilled in the art, unless the terms are additionally defined in the present invention. That is, the terms used in the following paragraphs should be read on the meaning commonly used in the related fields and will not be overly explained, unless the terms have a specific meaning in the present invention.

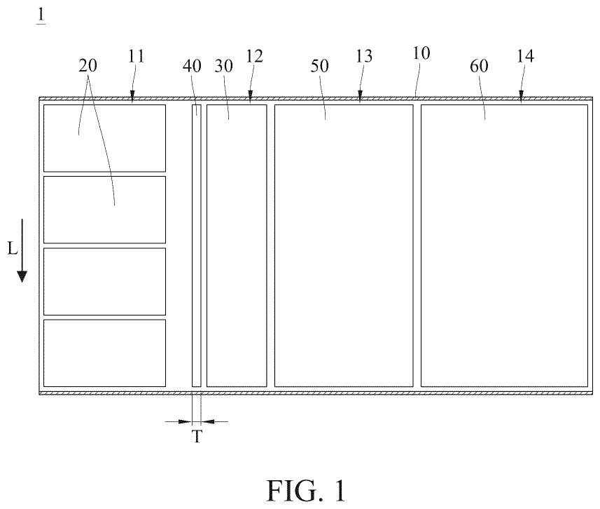

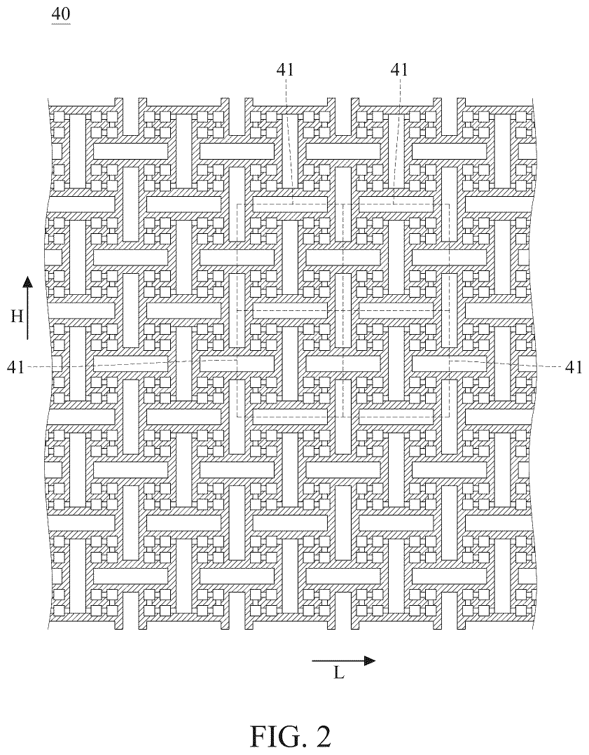

Referring to FIGS. 1 and 2, FIG. 1 is a schematic view of a server according to one embodiment of the invention, and FIG. 2 is a partial schematic view of a sound absorption structure in FIG. 1.

In this embodiment, the server 1 includes a casing 10, at least one hard disk module 20, a fan module 30 and a sound absorption structure 40. In addition, the server 1 may further include a motherboard 50 and a power supply module 60.

The casing 10 includes a hard disk storage area 11, a fan storage area 12, a motherboard storage area 13 and a power supply storage area 14. The hard disk storage area 11, the fan storage area 12, the motherboard storage area 13 and the power supply storage area 14 are sequentially arranged along a lengthwise direction of the casing 10. The hard disk module 20, the fan module 30, the motherboard 50, and the power supply module 60 are respectively disposed in the hard disk storage area 11, the fan storage area 12, the motherboard storage area 13 and the power supply storage area 14. The sound absorption structure 40 is disposed in the casing 10 and located between the hard disk storage area 11 and the fan storage area 12.

The sound absorption structure 40, for example, is a single-piece planar auxetic metamaterial that utilizes precisely designed micro internal structures, rather than relying on the chemical composition of conventional materials, to achieve special physical properties (such as negative mass density, negative Poisson's ratio, and negative refractive index) to block sound waves of specific frequencies. The sound absorption structure 40 is, for example, elastically deformable along a lengthwise direction L and a heightwise direction H thereof, and a thickness T of the sound absorption structure 40 is, for example, greater than or equal to 5 mm and less than or equal to 10 mm. The sound absorption structure 40 includes a plurality of sound absorption units 41, which are arranged in an array and connected to one another. This configuration allows the sound absorption structure 40 to adjust its sound absorption performance by applying different strains, enabling effective noise reduction for different frequencies. Since the structures of these sound absorption units 41 are identical, only one of them is described in detail below.

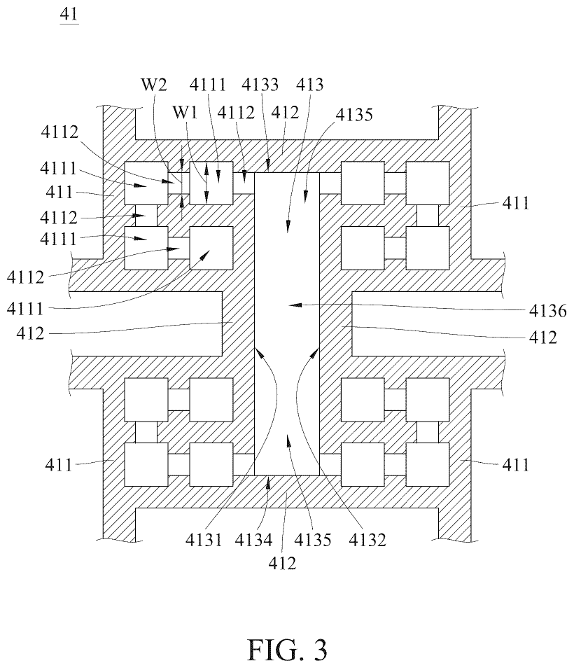

Then, referring to FIGS. 2 and 3, FIG. 3 is a schematic view of a sound absorption unit of the sound absorption structure in FIG. 2.

The sound absorption unit 41 includes a plurality of sub units 411 and a plurality of connection portions 412. The sub units 411 are arranged in an array and connected to one another via the connection portions 412 to surround a sound permeable slot 413 together. For example, the sound permeable slot 413 may be rectangular and include a first side 4131, a second side 4132, a third side 4133, a fourth side 4134, two end portions 4135 and a central portion 4136. The first side 4131 is opposite to the second side 4132, and the third side 4133 is opposite to the fourth side 4134. The two end portions 4135 and the central portion 4136 are located between the third side 4133 and the fourth side 4134, and the central portion 4136 is located between the two end portions 4135. The sound absorption unit 41 is, for example, a 20 mm×20 mm square and includes four sub units 411 and four connection portions 412, and the four sub units 411 are arranged in a 2×2 array. Two of the four sub units 411 and one of the four connection portions 412 are located at the first side 4131 of the sound permeable slot 413, and the others of the four sub units 411 and another of the four connection portion 412 are located at the second side 4132 of the sound permeable slot 413. The remaining two of the four connection portions 412 are located at the third side 4133 and the fourth side 4134 of the sound permeable slot 413, respectively.

Each of these sub units 411 includes a plurality of sound absorption chambers 4111 and a plurality of connecting channels 4112, where the sound absorption chambers 4111 are polygonal chambers. For example, in one of the sub units 411, the sub unit 411 is a hollow cube. The sub unit 411 includes four sound absorption chambers 4111 and four connecting channels 4112. The four sound absorption chambers 4111 are square chambers of the same size and arranged in a 2×2 array. Widths W1 of the sound absorption chambers 4111 are greater than widths W2 of the connecting channels 4112, and the sound absorption chambers 4111 and the connecting channels 4112 are alternately connected. That is, every two adjacent sound absorption chambers 4111 are connected via one connecting channel 4112, and the sound absorption chambers 4111 are arranged in series through the connecting channels 4112. One of the connecting channels 4112 of each sub unit 411 communicates with the sound permeable slot 413, and the sound absorption chambers 4111 of the sub units 411 communicate with the two opposite end portions 4135 of the sound permeable slot 413 through the connecting channels 4112. One of the connecting channels 4112 located at the first side 4131 and one of the connecting channels 4112 located at the second side 4132 are arranged with their openings facing each other. The sub units 411 may, for example, be Helmholtz resonators. When sound waves pass through the sound permeable slot 413 and enter the sound absorption chambers 4111 via the connecting channels 4112, the sound waves will resonate at specific frequencies, thereby absorbing and dissipating sound energy.

In this embodiment, the sound absorption structure 40 is disposed between the hard disk storage area 11 and the fan storage area 12, the sub units 411 of the sound absorption unit 41 of the sound absorption structure 40 are arranged in the array and connected to one another to surround the sound permeable slot 413 together, the sound absorption chambers 4111 and the connecting channels 4112 of each of the sub units 411 communicate with one another, and one of the connecting channels 4112 of at least one of the sub units 411 communicates with the sound permeable slot 413. By the aforementioned configuration, when the sound generated by the fan module 30 enters the sound absorption chambers 4111 via the connecting channels 4112 of the sub unit 411, the sound absorption chambers 4111 and the connecting channels 4112 form a continuous sound wave absorption structure in series. As the sound waves propagate through the sound absorption chambers 4111, the sound absorption path is extended. Specifically, when the sound waves enter the first sound absorption chamber 4111, resonance is induced within the first sound absorption chamber 4111, and the sound energy is transformed into thermal energy through resonance, thereby dissipating the sound. The portion of the sound waves that is not absorbed by the first sound absorption chamber 4111 passes through the connecting channel 4112 into the next sound absorption chamber 4111 for further absorption. During this process, the sound waves induce resonance within the sound absorption chambers 4111, and this resonance further enhances the sound absorption effect. The resonance phenomenon amplifies the sound waves at specific frequencies, thereby increasing the propagation path and absorption time of the sound waves within the sound-absorbing material, achieving a better sound absorption effect. Through the serial design of these sound absorption chambers 4111, a mechanism of multiple absorption and resonance is achieved, which can significantly reduce the reflection and transmission of sound waves, thereby achieving improved acoustic control. Therefore, the sound absorption structure 40 can effectively reduce the noise transmitted from the fan module 30 to the hard disk module 20, thereby preventing the noise from affecting the performance of the hard disk module 20.

Furthermore, the sound absorption chambers 4111 and the connecting channels 4112 of each sub unit 411 communicate with one another, and one of the connecting channels 4112 located at the first side 4131 and one of the connecting channels 4112 located at the second side 4132 are arranged with their openings facing each other. By this configuration, under different strains, the resonance frequency decreases, and the adjustable range of the resonance frequency is expanded, thereby enhancing the ability to regulate the resonance frequency.

Furthermore, the connecting channels 4112 of each sub unit 411 connected to the sound permeable slot 413 are located at one side of the sound permeable slot 413, and the sound absorption chambers 4111 are designed as the square chambers, which can enhance the noise reduction capability. In addition, the design of the sound absorption chambers 4111 as the square chambers increases the utilization of the structural space.

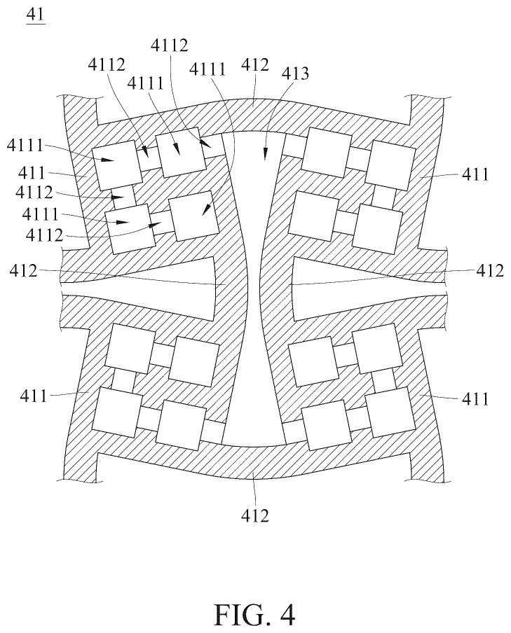

Previous studies observed that the performance of the hard disk module 20 deteriorates most significantly when the noise frequency is 3000 Hz. This may be because the noise at this frequency induces resonance within the hard disk, thereby affecting its read/write performance. In this embodiment, the sound absorption structure 40, in its undeformed state, can reduce noise at a frequency of approximately 3150 Hz, achieving a sound transmission loss (STL) greater than 5 dB, with a frequency bandwidth of 47 Hz. Furthermore, due to the negative Poisson's ratio characteristic of the planar auxetic material, applying different strains causes the sound absorption structure 40 to elastically deform. As a result, the sound absorption structure 40 can slightly adjust the applicable sound frequency for noise reduction under different stretching or compressing conditions. For example, referring to FIGS. 2 and 4, FIG. 4 is a schematic view of the deformed sound absorption unit in FIG. 3. After applying a strain of −0.1 to the sound absorption structure 40, the shape of the sound permeable slot 413 in the sound absorption unit 41 is compressed, allowing the sound absorption structure 40 to reduce noise at a frequency of approximately 3040 Hz, achieving a sound transmission loss (STL) greater than 5 dB, with a frequency bandwidth extended to 103 Hz. After applying a strain of 0.1 to the sound absorption structure 40, the shape of the sound permeable slot 413 in the sound absorption unit 41 is stretched, allowing the sound absorption structure 40 to reduce noise at a frequency of approximately 3060 Hz, achieving a sound transmission loss (STL) greater than 5 dB, with a frequency bandwidth narrowed to 33 Hz. Specifically, applying different strains affects the resonant frequency and frequency bandwidth of the sound absorption structure 40. Applying a positive strain reduces the effective frequency range of the sound absorption structure, while applying a negative strain shifts the resonant frequency toward lower frequency and significantly increases its effective frequency range. The sound absorption structure 40 is elastically deformable along the lengthwise direction L and the heightwise direction H thereof, and this flexibility enables the sound absorption structure 40 to adjust its noise reduction performance according to specific requirements, thereby providing optimal noise reduction effects in different application scenarios.

In this embodiment, during the design process of the sound absorption structure 40, theoretical methods are used for calculations, coupled with numerical simulations for validation, allowing for the rapid design of the sound absorption structure 40 that meets the requirements and helps reduce costs. In this embodiment, the sound absorption structure 40 is a planar auxetic material combined with the application of Helmholtz resonators. Compared to conventional sound absorption structures, the sound absorption structure 40 offers multiple advantages, including resonant frequency control, adjustable noise reduction bandwidth, and the equivalent stress required for strain. Additionally, the sound absorption structure 40 is a monolithic structure, which simplifies the assembly of the sound absorption structure 40, further reducing costs.

In this embodiment, by combining the sub-units 411 as Helmholtz resonators with planar auxetic materials exhibiting a negative Poisson's ratio, the configuration uses the advantage of planar auxetic materials being more easily deformable compared to conventional structures. Additionally, the structure allows for adjustment of ventilation rates, and its thickness is not affected by deformation, making it more suitable for application within the internal space of the server.

It should be noted that the sound absorption structures 40 in the above embodiment is not limited to being elastically deformable. In other embodiments, the sound absorption structure may be a non-deformable structure.

On the other hand, in the above embodiment, the sound absorption chambers of the sub units of the sound absorption unit communicate with the same sound permeable slot, but the invention is not limited thereto. In other embodiments, the sound absorption chambers of the sub units of the sound absorption unit may communicate with different sound permeable slots.

Furthermore, the shapes of the sound absorption units in the sound absorption structure of the above embodiment are not intended to limit the invention, but may be adjusted according to requirements.

According to the sound absorption structure and the server as discussed in the above embodiment, the sound absorption structure is disposed between the hard disk storage area and the fan storage area, the sub units of the sound absorption unit of the sound absorption structure are arranged in the array and connected to one another to surround the sound permeable slot together, the sound absorption chambers and the connecting channels of each of the sub units communicate with one another, and one of the connecting channels of at least one of the sub units communicates with the sound permeable slot. By the aforementioned configuration, the sound generated by the fan module can enter the sound absorption chambers through the connecting channels of the sub unit and be dissipated, thereby effectively reducing the noise transmitted from the fan module to the hard disk module and preventing the noise from affecting the performance of the hard disk module.

In addition, the configuration of the sound absorption structure that can elastically deform along the lengthwise and heightwise directions allows the sound absorption structure to provide noise reduction for different frequencies of sound.

Moreover, during the design process of the sound absorption structure, theoretical methods are used for calculations, coupled with numerical simulations for validation, allowing for the rapid design of the sound absorption structure that meets the requirements and helps reduce costs. Furthermore, the sound absorption structure is a monolithic structure, which simplifies the assembly of the sound absorption structure, further reducing costs.

In one embodiment of the invention, the server of the invention can be used for artificial intelligence (AI) computing, edge computing, as well as 5G server, cloud server, or vehicle-to-everything (V2X) server.

It will be apparent to those skilled in the art that various modifications and variations can be made to the present invention. It is intended that the specification and examples be considered as exemplary embodiments only, with a scope of the invention being indicated by the following claims and their equivalents.

What is claimed is:

1. A sound absorption structure, comprising:
at least one sound absorption unit, comprising a plurality of sub units, wherein the plurality of sub units are arranged in an array and connected to one another to surround a sound permeable slot together;
wherein each of the plurality of sub units comprises a plurality of sound absorption chambers and a plurality of connecting channels, the plurality of sound absorption chambers and the plurality of connecting channels communicate with one another; wherein one of the plurality of connecting channels of at least one of the plurality of sub units communicates with the sound permeable slot.

2. The sound absorption structure according to claim 1, wherein one of the plurality of connecting channels of each of the plurality of sub units communicates with the sound permeable slot.

3. The sound absorption structure according to claim 2, wherein the plurality of sub units comprises four sub units, the four sub units are arranged in a 2×2 array, two of the four sub units are located at one side of the sound permeable slot, and the others of the four sub units are located at another side of the sound permeable slot.

4. The sound absorption structure according to claim 3, wherein, in each of the plurality of sub units, the plurality of sound absorption chambers comprises four sound absorption chambers, the plurality of connecting channels comprises four connecting channels, the four sound absorption chambers are arranged in a 2×2 array, and the plurality of sound absorption chambers and the plurality of connecting channels are alternately connected.

5. The sound absorption structure according to claim 1, wherein, in each of the plurality of sub units, widths of the plurality of sound absorption chambers are greater than widths of the plurality of connecting channels.

6. The sound absorption structure according to claim 1, wherein the plurality of sound absorption chambers of each of the plurality of sub units have a same size.

7. The sound absorption structure according to claim 1, wherein the plurality of sound absorption chambers of each of the plurality of sub units are square chambers.

8. The sound absorption structure according to claim 1, wherein the plurality of sub units are Helmholtz resonators.

9. The sound absorption structure according to claim 1, wherein the sound absorption structure is elastically deformable in a lengthwise direction and a heightwise direction thereof.

10. A server, comprising:
a casing, comprising a hard disk storage area and a fan storage area;
a hard disk module, disposed in the hard disk storage area;
a fan module, disposed in the fan storage area; and
a sound absorption structure, disposed between the hard disk storage area and the fan storage area and comprising:
at least one sound absorption unit, comprising a plurality of sub units, wherein the plurality of sub units are arranged in an array and connected to one another to surround a sound permeable slot together;
wherein each of the plurality of sub units comprises a plurality of sound absorption chambers and a plurality of connecting channels, the plurality of sound absorption chambers and the plurality of connecting channels communicate with one another; wherein one of the plurality of connecting channels of at least one of the plurality of sub units communicates with the sound permeable slot.
